(19) United States
(12) Patent Application Publication
(10) Pub. No.: US 2010/0314728 A1
(43) Pub. Date: Dec. 16, 2010

(54) IC PACKAGE HAVING AN INDUCTOR ETCHED INTO A LEADFRAME THEREOF

(76) Inventor: Tung Lok Li, Hong Kong (CN)

Correspondence Address: WINSTEAD PC, P.O. BOX 50784, DALLAS, TX, 75201, US

(21) Appl. No.: 12/816,974

(22) Filed: Jun. 16, 2010

Related U.S. Application Data
(60) Provisional application No. 61/187,662, filed on Jun. 16, 2009.

(51) Int. Cl. H01L 23/495; H01L 21/50

(52) U.S. Cl. 257/666; 438/123; 257/E21.499; 257/E23.031

(57) ABSTRACT

A leadless integrated circuit (IC) package comprising an IC chip mounted on a metal leadframe and a plurality of electrical contacts electrically coupled to the IC chip. The leadframe having a spiral inductor etched therein.

### CROSS-REFERENCE TO RELATED APPLICATIONS

This patent application claims priority to U.S. Provisional Patent Application Ser. Nos. 61/187,662, filed 16 Jun. 2009, which is hereby incorporated by reference. This Application is related to PCT Application Serial Nos. PCT/CN2009/072030, filed 27 May 2009; PCT/CN2009/001320, filed 26 Nov. 2009; and PCT/CN2010/00239, filed 26 Feb. 2010, each of which is hereby incorporated by reference.

### BACKGROUND

1. Technical Field

The present invention relates generally to integrated circuit (IC) packaging technology and, in particular, but not by way of limitation, to leadless IC packages having inductors etched into leadframes thereof.

2. Background

IC packaging is one of the final stages involved in the fabrication of IC devices. During IC packaging, one or more IC chips are mounted on a package substrate, connected to electrical contacts, and then coated with an encapsulation material comprising an electrical insulator such as epoxy or silicone molding compound. The resulting structure, commonly known as an “IC package,” may then be mounted onto a printed circuit board (PCB) and/or connected to other electrical components.

In most IC packages, the IC chip is completely covered by the encapsulation material, while the electrical contacts are at least partially exposed so that they can be connected to other electrical components. In other words, the electrical contacts are designed to form electrical connections between the IC chip inside the package and electrical components outside the IC package. Oftentimes, using a metal leadframe (LF) to form part of the IC package may be more cost effective than using a laminated board or tape material because, for example, more cost effective materials may be used, such as copper, nickel, or other metals or metal alloys, and use of such materials may allow more cost effective manufacturing processes to be employed, such as stamping or etching rather than multi-step laminate processes. One of the most common designs for these electrical contacts is one in which they form “leads” extending out from the sides of the encapsulating material. The leads typically are bent downward to form connections with electrical components on a PCB.

Recognizing these and other problems with conventional IC packages, researchers have developed IC packages in which the external leads are replaced by electrical contacts that are covered on top by the encapsulating material but exposed on the bottom of the IC package so they can be connected to electrical components located beneath the IC package. These IC packages, referred to as “leadless” IC packages, tend to occupy less space compared with conventional IC packages due to the absence of the external leads. In addition, these IC packages eliminate the need to bend the leads to form connections. Some examples of conventional leadless IC packages are disclosed in U.S. Pat. Nos. 6,498,099 and 7,049,177, the respective disclosures of which are hereby incorporated by reference. Among other things, these patents describe and illustrate design variations for leadless IC packages and various techniques for manufacturing and using the leadless IC packages.

### SUMMARY

Various embodiments disclosed in this application contemplate leadless integrated circuit (IC) packages having inductors etched into a leadframe thereof and methods of manufacturing. In one embodiment, a leadless integrated circuit (IC) package is shown including a metal leadframe having a top surface and a bottom surface, the metal leadframe comprising a plurality of terminals extending from the top surface to the bottom surface, each of the plurality of terminals comprising a bonding area at the top surface, a contact area at the bottom surface, and a metal trace coupling the bonding area to the contact area. The IC package may also include an IC chip mounted on the top surface of the metal leadframe and comprising a plurality of bonding pads, a plurality of wires, each of the plurality of wires bonded to a bonding area and a bonding pad, an encapsulation compound covering the IC chip, the plurality of wires, and at least a portion of each of the plurality of terminals, wherein the contact areas of the plurality of terminals are not fully encapsulated by the encapsulation compound, wherein at least one of the plurality of metal traces comprises an inductor.

The above summary is not intended to represent each embodiment or every aspect of the present invention.

### BRIEF DESCRIPTION OF THE DRAWINGS

A more complete understanding of various embodiments of the present invention may be obtained by reference to the following Detailed Description when taken in conjunction with the accompanying Drawings, wherein:

FIG. 1 illustrates an embodiment of a spiral inductor;

FIG. 2 illustrates a side view of a cross section along line X-X of FIG. 1;

FIG. 3 illustrates a magnified view of Detail A of FIG. 2;

FIGS. 4A-4C illustrate various embodiments of spiral inductors;

FIGS. 5A-5B illustrate top and bottom views of an IC package having a spiral inductor

FIGS. 6A-E illustrate aspects of an embodiment of a leadless IC package at various stages of a manufacturing process; and

FIG. 7 illustrates thought a flowchart an embodiment of a process for manufacturing a partially etched leadframe.

### DETAILED DESCRIPTION OF ILLUSTRATIVE EMBODIMENTS

Various embodiments of the present invention will now be described more fully with reference to the accompanying drawings. The invention may, however, be embodied in many different forms and should not be construed as limited to the embodiments set forth herein; rather, the embodiments are provided so that this disclosure will be thorough and complete, and will fully convey the scope of the invention to those skilled in the art.

As described in more detail below, various embodiments of leadless IC packages may be formed from leadframes by etching patterns in top and/or bottom surfaces of the leadframe. In some embodiments, one or more IC chips may be disposed in central portions of the IC packages and covered by an encapsulation compound and adapted to be electrically coupled to an external device, such as a PCB, through a plurality of terminals. In some embodiments, electrical connections may be formed using wire bonds to connect the IC chips to various bonding areas. Some IC packages may include one or more metal traces adapted to route electrical connections from the bonding areas to contact areas on a bottom surface of the leadframe.

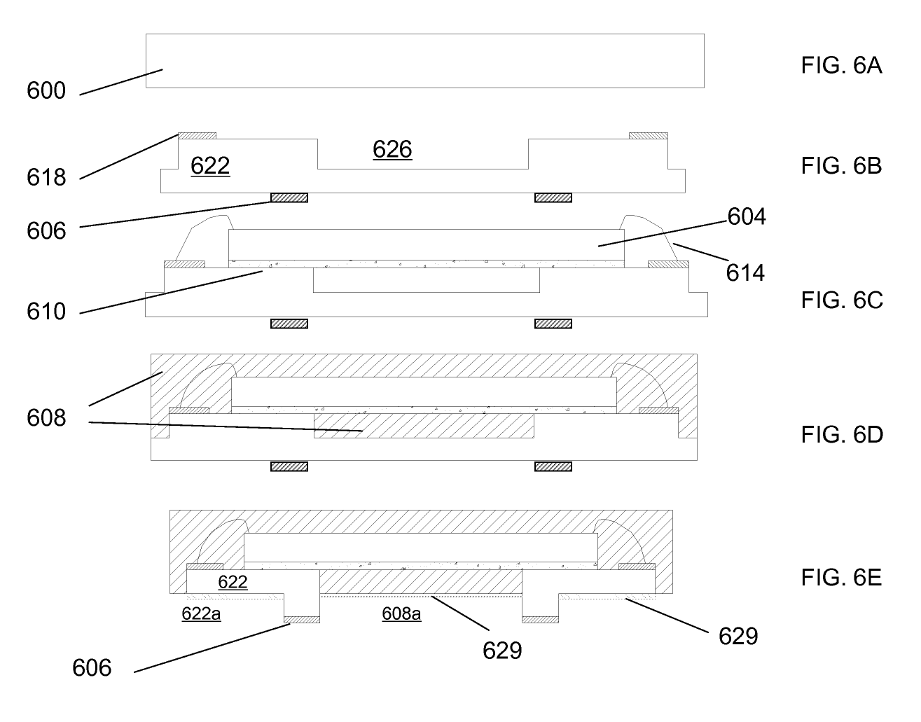

Referring first to FIGS. 6A-6E, there are shown cross-sectional side views of an embodiment of an IC package at various stages of a manufacturing process. For descriptive purposes, the manufacturing process has been described relative to a single IC package, but the steps of the manufacturing process may be applied to some or all of a plurality of device areas disposed on a leadframe strip. Referring now to FIG. 6A, the process begins with an unetched leadframe 600, such as a metal strip having generally flat top and bottom surfaces. Oftentimes, a manufacturer may receive design criteria for an IC package, such as, for example, the size of an IC chip to be mounted to the leadframe and a pattern of an inductor or the number of bonding areas to be disposed on a top surface of the leadframe. The design criteria may also include the size and location of contact areas to be disposed on a bottom surface of the leadframe. The distance between the contact areas, or pitch, may be dependent on the minimum requirements of an electronic component the IC package will be mounted to, such as, for example, a PCB. In FIG. 6B, the leadframe 600 is partially etched on a top surface to create recesses 626 defining metal traces 622 thereon. In the embodiment shown, a metal plating has been added to bonding areas 618 disposed on a top surface of the metal traces 622 and to contact areas 606 disposed on a bottom surface of the metal traces 622. The metal plating of the bonding areas 618 and contact areas 606 may be formed by applying a bondable material or solderable to the metal traces 622, such as, for example, a plated or clad metal such as silver (Ag), gold (Au), copper (Cu), or other bondable materials. In various embodiments, the etching of the top surface of the leadframe 600 may be done at a first location, such as a manufacturing plant, and the remaining steps may be done at a second location, such as, for example, a different area of the manufacturing plant or a different manufacturing plant. In such embodiments, by partially etching the leadframe 600, the metal traces 622 are more stable and less likely to move than if the leadframe 600 were etched all the way through.

In FIG. 6C, it may be seen that an IC chip 604 has been secured to the leadframe 600 using an adhesive material 610, for example, an epoxy. After the IC chip is mounted to the leadframe 600, the IC chip may be electrically coupled to the bonding areas disposed outside of the die-attach area, for example, via wire bonds 614. In FIG. 6D, an encapsulation compound 608 (shown as shaded areas) has been applied to encapsulate the IC chip 604 and the wire bonds 614. In addition, the encapsulation compound 608 has also filled in the recesses 626, including those recesses 626 disposed under the IC chip 604. In FIG. 6E, a bottom surface of the leadframe 600 has been etched back. In various embodiments, the etching back of the bottom surface may include etching portions 608a of the leadframe 600 corresponding to the recesses that were formed in a top surface of the leadframe 600 to completely etch through the leadframe 600, thereby electrically isolating the metal traces 622 one from another such that the remaining portions of the leadframe 600 electrically couple the bonding areas 618 to the contact areas 606 via metal traces 622. In some embodiments, the etching back may include exposing a bottom surface of portions of the encapsulation compound 608. In various embodiments, the etching back may include etching portions 622a of some of the metal traces 622. As can be seen in the embodiment shown, the bonding areas 618 are laterally remotely disposed from the contact areas 606 such that no line perpendicular to the top surface of the leadframe 600 intersects both a bonding area and a contact area. In various embodiments, the metal traces 622 may be configured to provide an electrical pathway, or routing, from the bonding area 618 to the laterally remotely disposed contact area 606 disposed underneath the IC chip 604. In some embodiments, a protective coating 629 may be added to a portion of bottom surfaces of the metal traces 622. In some embodiments, the protective coating 629 may be added to various lower surfaces of the leadframe 600 and encapsulation compound 608.

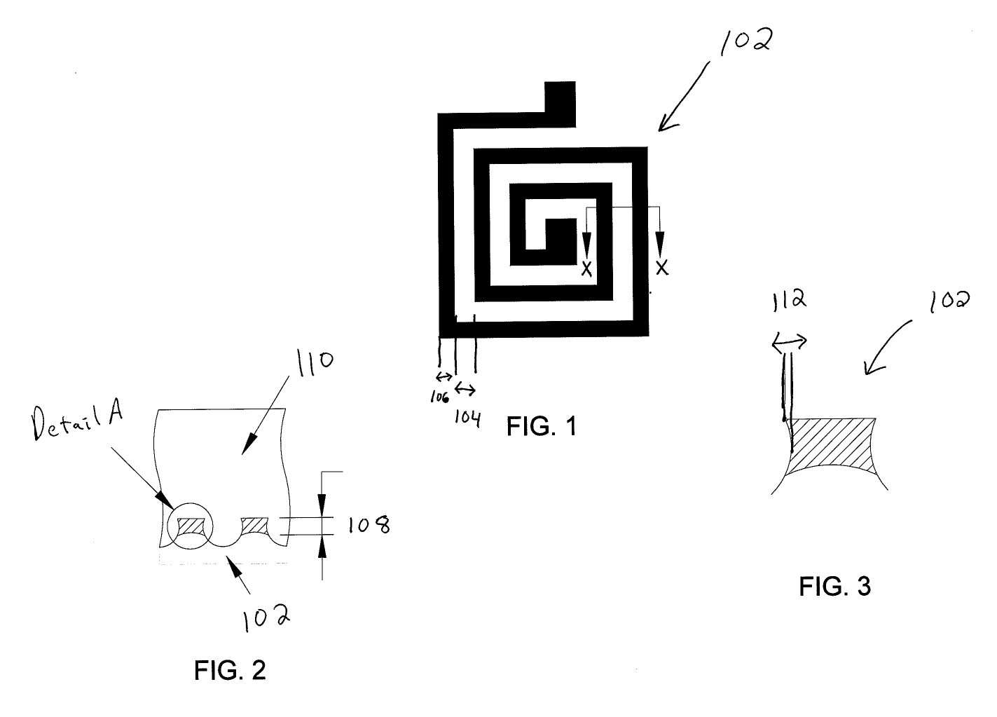

Referring now to FIG. 1, an inductor 102 is shown as a darkened area. In various embodiments, the inductor 102 may be any of any shape. In the embodiment shown, the inductor 102 is a generally spiral-shaped inductor. As used herein, the term “spiral” includes any shape that emanates from a central location, getting progressively farther away from the central location as it revolves around the central location and includes spirals formed from curved regions (true spirals), straight-line segments (or spirangles), or a combination of both curves and straight-line segments. In various embodiments, the spiral inductor 102 may be formed by etching a top surface and/or a bottom surface of various portions of a metal leadframe, such as, for example, a copper leadframe. The spiral inductor 102 may be formed by etching away portions of the metal leadframe to form recesses 104 therein leaving raised portioned 106 between the recesses 104. In some embodiments, the recesses 104 may be, for example, on the order of between 3 mils and 5 mils, or may be wider or thinner. In some embodiments, the raised portions 106 may be, for example, on the order of between 2 mils and 4 mils, or may be wider or thinner. In various embodiments, the geometrical characteristics of the spiral inductor 102 may be used to vary the performance of the inductor.

Referring now to FIG. 2, there is shown a side view of a cross-section along line X-X of FIG. 1. As can be seen from this view, the spiral inductor 102 includes raised portions and recesses disposed therebetween. The height of the raised portions 108 may be, for example, on the order of between 1 mil and 2 mils, or may be taller or shorter. In the embodiment shown, an encapsulation compound 110 has been applied to a top surface of the leadframe and filled in the recesses between the raised portions. In the embodiment shown, the raised portions are not electrically isolated from each other. After the encapsulation compound is applied, a back etch step may be utilized in some embodiments to remove the portions of the leadframe between the raised portions 108 and thereby electrically isolate the raised portions.

Referring now to FIG. 3, there is shown a magnified view of Detail A of FIG. 2 illustrating a single raised portion of the spiral inductor 102. In this view, it can be seen that the side walls of the raised portion of the spiral inductor 102 may be etched such that a top surface of the raised portion is wider than a middle portion thereof. In various embodiments, the distance of overcut 112 may be, for example, on the order of 0.3 mils, or may be more or less. Various patterns and shapes may be utilized to vary the performance characteristics of the spiral inductor 102.

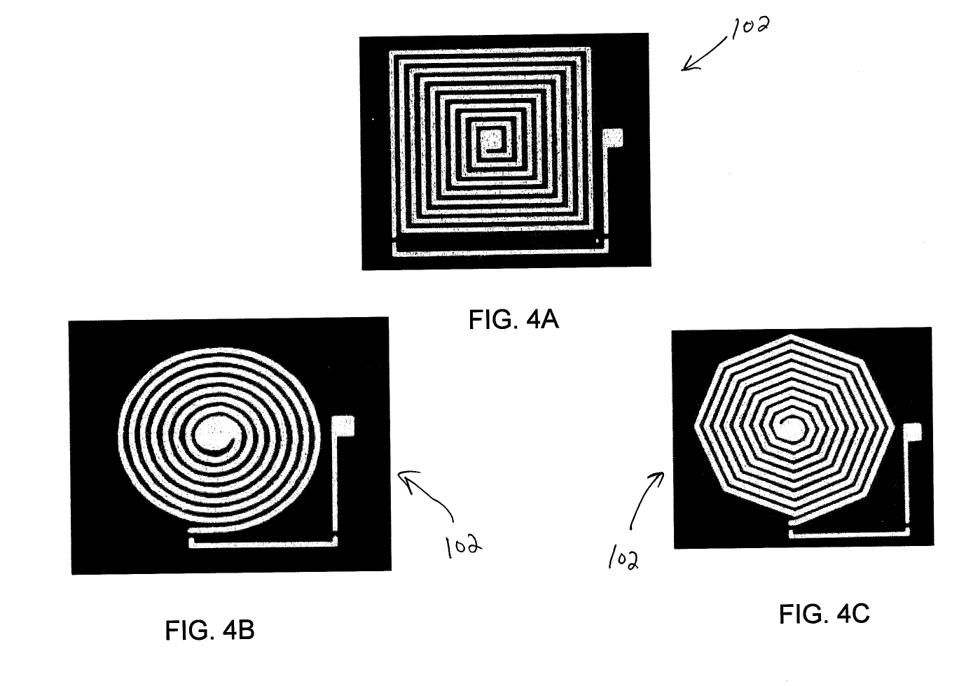

Referring now to FIGS. 4A-4C, there is shown various embodiments of spiral inductors 102 that may be formed in a leadframe. In FIG. 4A, a generally square-shaped spiral inductor 102 is shown. In FIG. 4B, a generally circular-shaped spiral inductor is shown. In FIG. 4C, a generally polygonal-shaped spiral inductor 102 is shown. While three different spiral shapes are shown in FIGS. 4A-4C, any number of different shapes may be utilized depending on the desired characteristics of the inductor.

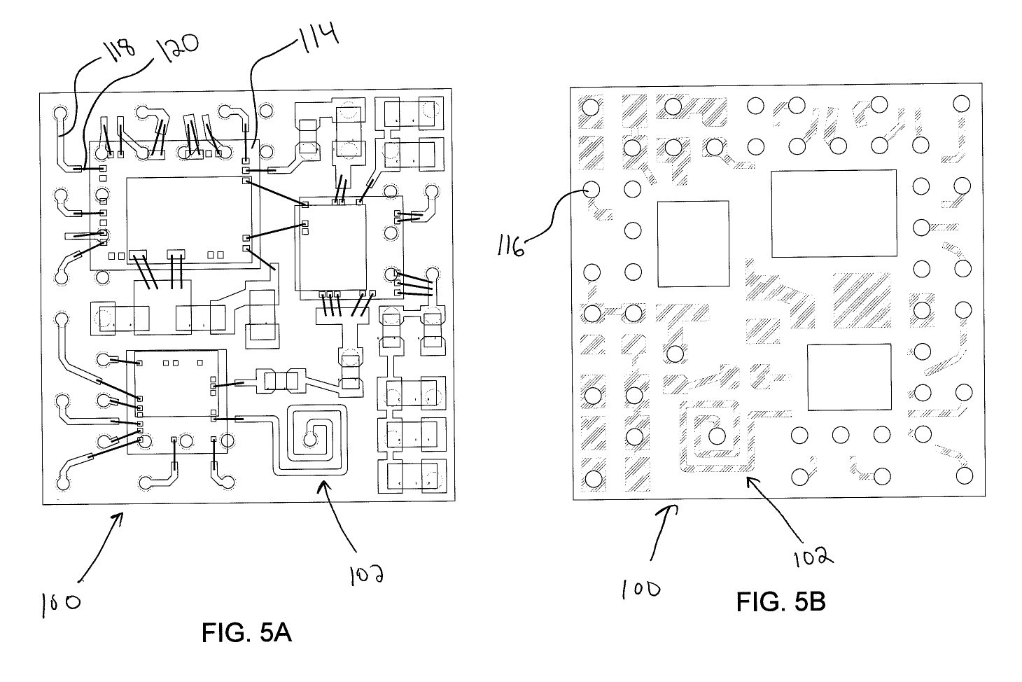

Referring now to FIGS. 5A-5B, an IC package 100 is shown having a system-in-package configuration. FIG. 5A shows a top view of the IC package 100 including a spiral inductor 102, a plurality of electrical components 114 (some active and some passive), a plurality of wire bonds 120, a plurality of metal traces 118, and a plurality of contact pads 116. FIG. 5B shows a bottom view of the IC package 100 where the non-shaded areas represent encapsulation compound and the shaded areas represent portions of the metal leadframe. In some embodiments, the IC chips of the IC package may be mounted directly over the spiral inductor. For example, an IC chip may be larger than the spiral inductor and may cover all or some of the spiral inductor. In other embodiments, the IC chip may be smaller than the spiral inductor and the spiral inductor may be underneath all or some of the IC chip.

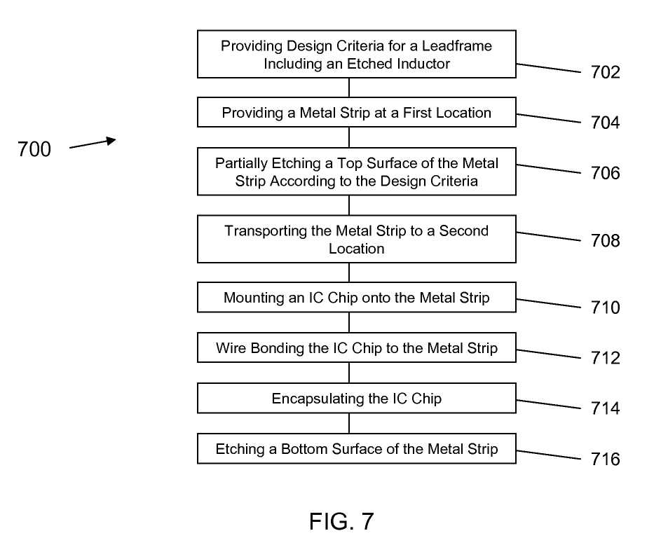

Referring now to FIG. 7, there is shown a flow chart of an embodiment of an IC package manufacturing process 700. The process begins at step 702 when design criteria for a partially etched leadframe are provided to a manufacturer. In various embodiments, at least a portion of the design criteria may be received through a customer order and/or developed by the manufacturer. The design criteria may include information relative to a final IC package and/or may include only information relative to a partially etched leadframe. For example, the design criteria may include the length, width, and height of a desired leadframe, the size of the IC chip to be mounted onto the leadframe, the size and pattern of an inductor, the number of bonding areas, the location of the bonding areas, the number of contact areas, the location of the contact areas, and/or other design criteria. At step 704, a first location is provided with an unetched metal strip, such as, for example, a metal strip of copper. At step 706, the metal strip is partially etched on a top surface using any number of etching processes to create a pattern of recesses defining upper portions of metal traces having bonding areas disposed thereon. The pattern of recesses may correspond to the metal traces needed to couple the bonding areas to the locations of the contact areas as may be provided in the design criteria. In some embodiments, the etch may be a half-etch, such that the recesses formed in the leadframe extend halfway therethrough. For example, in a 4 mil leadframe, the half-etch would be a 2 mil etch. In various embodiments, the leadframe may be etched more or less than halfway therethrough. For example, in some embodiments, the partial etching may be to a depth on the order of 3 mils+/−0.5 mils. After the top surface has been partially etched, one or both of the top and bottom surfaces of the leadframe may be selectively plated, such as, for example, by plating the bonding areas and/or the locations of where the contact areas will be disposed. The metal plating of the bonding areas may be formed by applying a bondable material to the metal traces. In various embodiments, a surface adhesion enhancement treatment (“AE treatment”), such as, for example, roughening and/or cleaning the surface to increase adhesion, may follow the metal plating.

At step 708, the partially etched leadframe may be transported from the first location to a second location. In various embodiments, the partially etched leadframe provides stability for the metal traces during transportation. For example, in some embodiments, the first location may be a portion of a manufacturing plant adapted for etching the top surface of the leadframe and the second location may be the same or a different portion of the manufacturing plant adapted to complete the IC packaging process. In some embodiments, the first location may be a first manufacturing plant and the second location may be a second manufacturing plant. In some embodiments, the first location may be a first manufacturing plant and the second location may be a customer's location or other location. At step 710, an IC chip is mounted onto the partially etched leadframe. Next, the IC chip is wire bonded to the partially etched leadframe at step 712 followed by encapsulation of the IC chip at step 714. The process ends with a back etching of a bottom surface of the metal strip at step 716.

Although various embodiments of the method and system of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth herein.

What is claimed is:

1. A method of manufacturing a leadframe for an integrated circuit (IC) package, the method comprising:
receiving design criteria for a partially patterned leadframe for use in an IC package, the design criteria including a design of an inductor to be disposed on a top surface of the leadframe, a first pattern of locations of a plurality of bonding areas to be disposed on the top surface of the leadframe, and a second pattern of locations of a plurality of contact areas to be disposed on a bottom surface of the leadframe;
providing a metal strip having a top surface and a generally flat bottom surface;
etching the top surface of the metal strip to define the inductor, the plurality of bonding areas at the locations of the first pattern and to define upper portions of a plurality of metal traces, the plurality of metal traces coupling the locations of the first pattern of the plurality of bonding areas on the top surface of the metal strip to the locations of the second pattern of the plurality of contact areas on the bottom surface of the metal strip; and
wherein at least one of the plurality of metal traces forms a spiral-shaped inductor electrically coupling a bonding area to a contact area laterally disposed therefrom.

2. The method of claim 1 comprising mounting an IC chip to the top surface of the metal strip.

3. The method of claim 2 comprising wirebonding the IC chip to the bonding area electrically coupled to the spiral-shaped inductor.

4. The method of claim 1 wherein the spiral-shaped inductor is a spirangle.

5. The method of claim 1 wherein the spiral-shaped inductor is a four-angle spirangle.

6. The method of claim 1 wherein the spiral-shaped inductor is an eight-angle spirangle.

7. The method of claim 1 wherein the design criteria include an overcut depth to be etched into sidewalls of the spiral-shaped inductor.

8. A leadframe for an integrated circuit (IC) package comprising:
a metal strip having top and bottom surfaces;
the metal strip having a patterned recess formed in the top surface thereof, the patterned recess being limited in depth and extending partially through to the bottom surface, the patterned recess defining upper portions of a plurality of metal traces extending from the top surface to the bottom surface of the metal strip;
the plurality of the metal traces comprising a bonding area disposed on the top surface of the metal strip and a contact area disposed on the bottom surface of the metal strip, the metal trace electrically coupling the bonding area to the contact area;
the bonding areas and the contact areas having metal plating applied thereto such that when portions of the metal strip disposed between the plurality of metal traces are etched away, the plurality of metal traces coupling the bonding areas to the contact areas are electrically isolated from one another; and
wherein at least one of the plurality of metal traces is a spiral-shaped inductor.

9. The leadframe of claim 8 wherein the patterned recess is etched into the top surface of the metal strip.

10. The leadframe of claim 8 wherein a plurality of the metal traces have a width of less than 2 mils.

11. The leadframe of claim 8 wherein a plurality of the bonding areas have a pitch less than a pitch of the contact areas coupled thereto.

12. The leadframe of claim 8 wherein the spiral-shaped inductor is a spirangle.

13. The leadframe of claim 8 wherein the spiral-shaped inductor includes sidewalls having an overcut of less than 0.3 mils.

14. A method of manufacturing a leadframe for an integrated circuit (IC) package, the method comprising:
providing a metal strip having a top surface and a generally flat bottom surface;
etching a pattern into the top surface of the metal strip defining upper portions of a plurality of metal traces, each metal trace extending from the top surface to the bottom surface of the metal strip and having a bonding area disposed on the top surface thereof and a contact area disposed on the bottom surface thereof;
applying a metal plating to each bonding area and each contact area;
wherein, when remaining portions of the metal strip disposed between the plurality of metal traces are etched away, the plurality of metal traces are electrically isolated from one another; and
wherein at least one of the plurality of metal traces is a spiral-shaped inductor.

15. The method of claim 14, wherein the pattern is etched into the top surface of the metal strip in at least partial dependence on design criteria of the IC package.
